(19) United States
(12) Patent Application Publication
(10) Pub. No.: US 2026/0198245 A1
(43) Pub. Date: Jul. 9, 2026

(54) Semiconductor Manufacturing System and Method to Improve Wafer Reconstitution and Reduce Wafer Thickness

(71) Applicant: STATS ChipPAC Pte. Ltd., Singapore (SG)

(72) Inventors: Yi Jing Eric Chong, Singapore (SG); Abelardo Hadap Advincula, JR., Singapore (SG); Linda Pei Ee Chua, Singapore (SG)

(73) Assignee: STATS ChipPAC Pte. Ltd., Singapore (SG)

(21) Appl. No.: 19/010,576

(22) Filed: Jan. 6, 2025

(51) Int. Cl. H01L 23/00; H01L 21/56; H01L 21/78

(52) U.S. Cl. CPC H10P 54/00; H10W 74/014; H10W 70/09; H10W 72/0198

(57) ABSTRACT

A semiconductor device has a semiconductor substrate and a notch formed around a perimeter of the semiconductor substrate. The semiconductor substrate has a curved surface formed around a perimeter of the semiconductor substrate. A portion of the semiconductor substrate is removed to reduce a thickness of the semiconductor wafer. A first encapsulant is deposited over the semiconductor substrate. The semiconductor substrate is singulated into a plurality of semiconductor die. The semiconductor die are disposed on a carrier as a reconstituted substrate. A second encapsulant is deposited over the reconstituted substrate. A portion of the second encapsulant is removed to reduce a thickness of the reconstituted substrate. An interconnect structure is formed over the semiconductor die and second encapsulant. Bumps are formed over the interconnect structure. A thickness of the semiconductor die is less than 100 micrometers. The reconstituted substrate has a flexible property.

### FIELD OF THE INVENTION

The present invention relates in general to semiconductor devices and, more particularly, to a semiconductor manufacturing system and method to improve wafer reconstitution and reduce wafer thickness without warpage.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor die are typically formed as a semiconductor wafer. The semiconductor die are singulated from the semiconductor wafer and can be reconstituted on a separate carrier for further processing, such as external interconnect and protection. An encapsulant is deposited over the reconstituted substrate. The reconstituted substrate has a thickness on the order of 350 micrometers (μm) or more. The encapsulant has a thickness on the order of 150 μm. The reconstituted substrate thickness is necessary to prevent warpage after depositing the encapsulant. Any lower thickness of the reconstituted substrate could be counter to maintaining the integrity of the wafer structure and make subsequent processing difficulty in terms of handling and wafer breakage.

### BRIEF DESCRIPTION OF THE DRAWINGS

FIGS. 1a-1b illustrate a semiconductor wafer with a plurality of semiconductor die separated by a saw street;

FIGS. 2a-2o illustrate a process of forming a semiconductor wafer with reduced thickness and covered by a first encapsulant;

FIGS. 3a-3j illustrate a process of forming a reconstituted substrate with reduced thickness semiconductor die and covered by a second encapsulant; and

FIG. 4 illustrates flexibility of the reconstituted substrate having reduced thickness semiconductor die and covered by the second encapsulant; and

FIG. 5 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

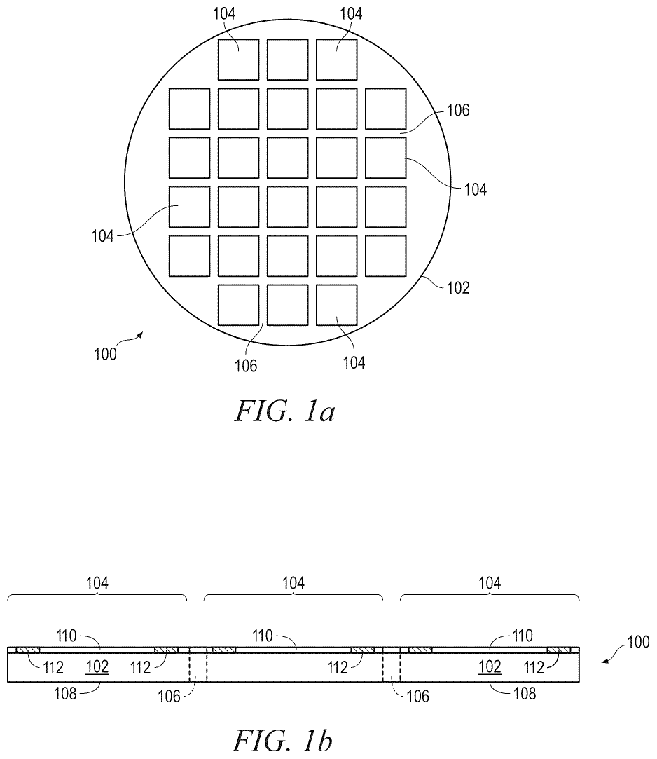

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 is circular with a diameter of 100-450 millimeters (mm). Semiconductor wafer 100 can be rectangular or any other geometric shape.

FIG. 1b shows a cross-sectional view of a portion of semiconductor wafer 100. Each semiconductor die 104 has a back or non-active surface 108 and an active layer 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active layer 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over or within active layer 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits in active layer 110.

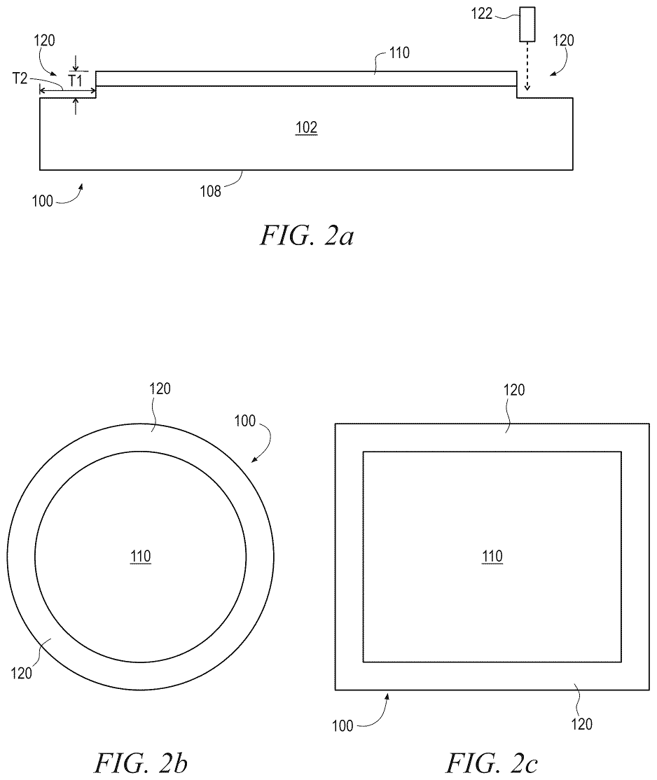

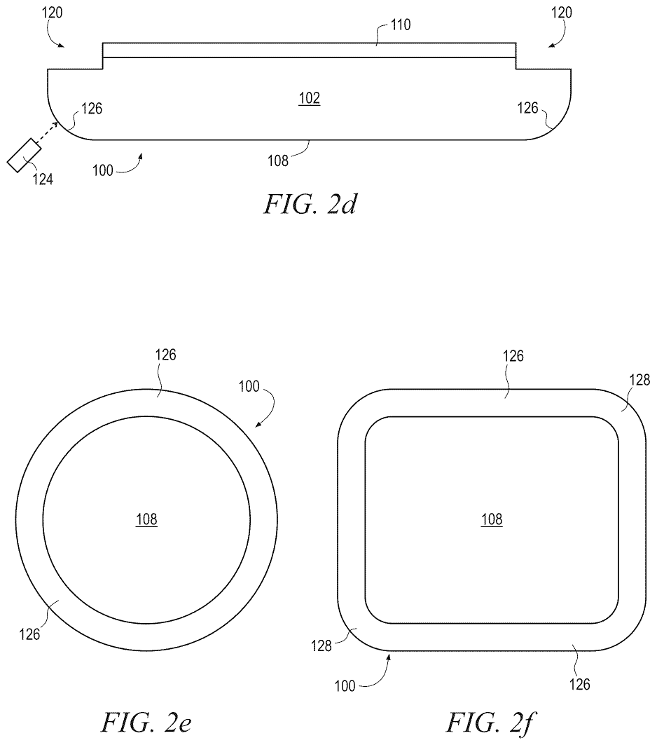

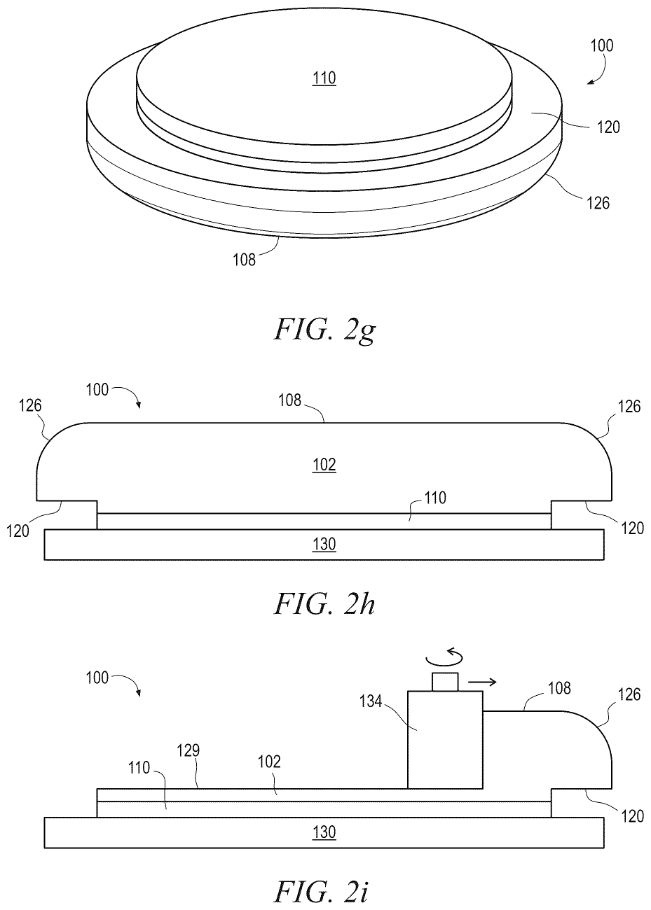

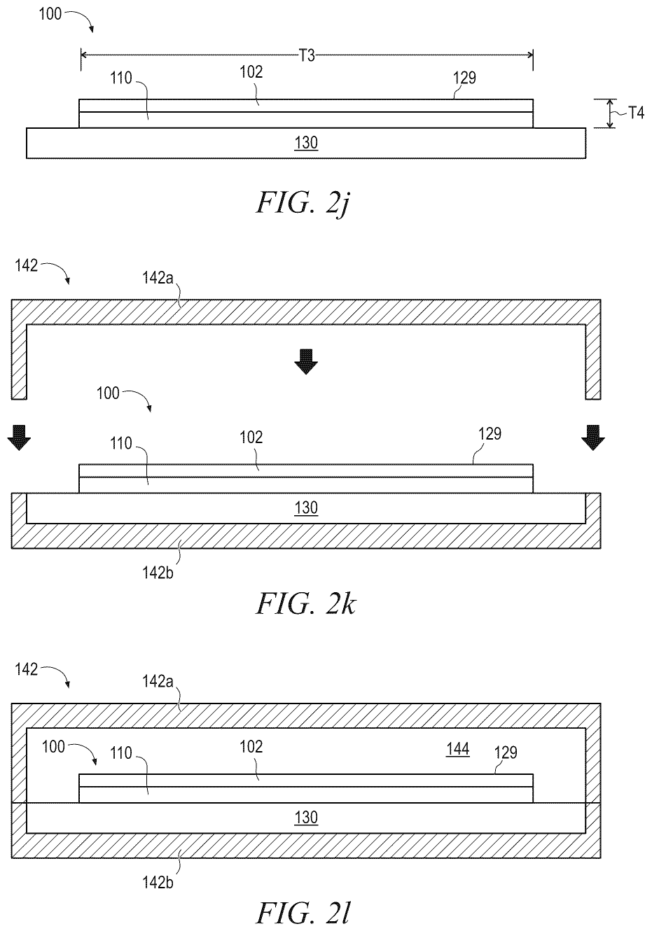

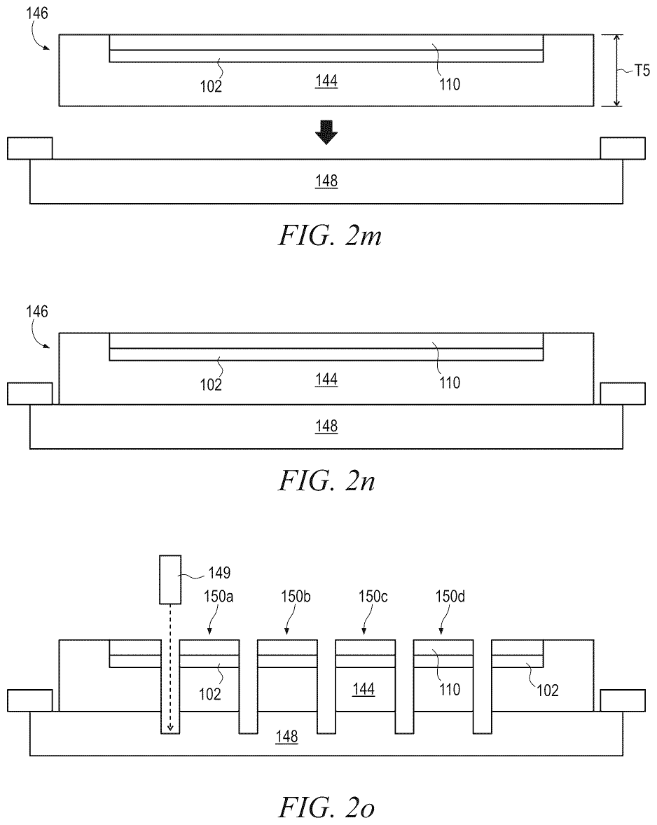

FIGS. 2a-2o illustrate a process of forming a semiconductor wafer with reduced thickness and covered by a first encapsulant. FIG. 2a shows a cross-sectional view of semiconductor wafer 100 with base semiconductor material 102 and active layer 110. A portion of active layer 110 and possibly semiconductor material 102 is removed by an etching process or laser direct ablation (LDA) using layer 122 to form a notch or edge trim 120. In one embodiment, notch 120 has dimensions T1 of 120 μm and T2 of 1.5 mm. FIG. 2b shows a top view of notch 120 formed in active layer 110 around a perimeter of a circular semiconductor wafer 100. In the case of a rectangular semiconductor wafer 100, FIG. 2c shows a top view of notch 120 formed in active layer 110 around a perimeter of the rectangular semiconductor wafer.

In FIG. 2d, a portion of semiconductor material 102 is removed by etching or LDA using laser 124 to form a rounded edge 126. The rounded edge 126 extends from notch 120 to back surface 108. FIG. 2e shows a top view of rounded edge 126 formed in semiconductor material 102 around a perimeter of a circular semiconductor wafer 100. In the case of a rectangular semiconductor wafer 100, FIG. 2f shows a top view of rounded edge 126 and rounded corners 128 formed in semiconductor material 102 around a perimeter of the rectangular semiconductor wafer. FIG. 2g is a perspective view of notch 120 and rounded edge 126 is a circular semiconductor wafer 100.

In FIG. 2h, semiconductor wafer 100 from FIG. 2d is inverted and placed on double-side heat resistant tape 130. Tape 130 secures semiconductor wafer 100 in place for a backgrinding operation. In FIG. 2i, semiconductor wafer 100 undergoes a backgrinding operation using grinder 134 to remove a portion of semiconductor material 102 down to surface 129. FIG. 2j shows semiconductor wafer 100 post grinding with dimensions T3 of 300 mm and T4 of 100 μm.

In FIG. 2k, semiconductor wafer 100 from FIG. 2j is placed in chase mold 142. Upper chase mold housing 142a of chase mold 122 is disposed over semiconductor wafer 100 resting in lower chase mold housing 142b. FIG. 2l shows semiconductor wafer 100 disposed within chase mold 142 between upper chase mold housing 142a and lower chase mold housing 142b. An encapsulant 144 is injected into the compartment between upper chase mold housing 142a and lower chase mold housing 142b and deposited over semiconductor wafer 100 as disposed within chase mold 142. Encapsulant 144 can be polymer composite material, such as epoxy resin with filler, epoxy acrylate with filler, or polymer with proper filler. Encapsulant 144 is non-conductive, provides structural support, and environmentally protects the semiconductor device from external elements and contaminants.

In FIG. 2m, assembly 146 comprising semiconductor wafer 100 and encapsulant 144 is removed from chase mold 142 and disposed over dicing tape 148. In one embodiment, encapsulant 144 has a thickness T5 of 350 μm. FIG. 2n shows assembly 146 disposed on dicing tape 148.

In FIG. 2o, assembly 146 is singulated using saw blade or laser cutting tool 149 into individual semiconductor die, shown as semiconductor die 150a-150d. Each semiconductor die 150a-150d includes a portion of active layer 110, semiconductor material 102, and encapsulant 144.

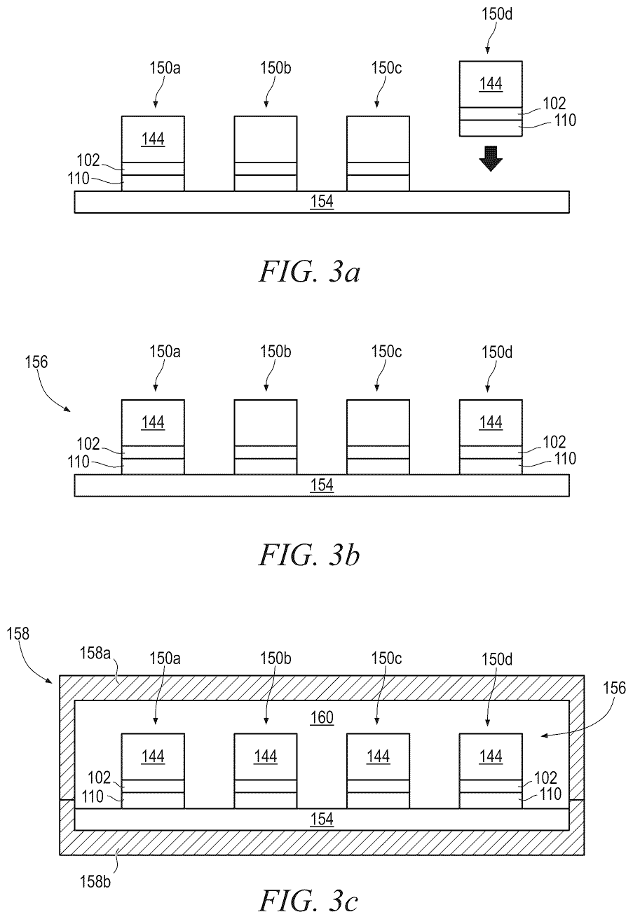

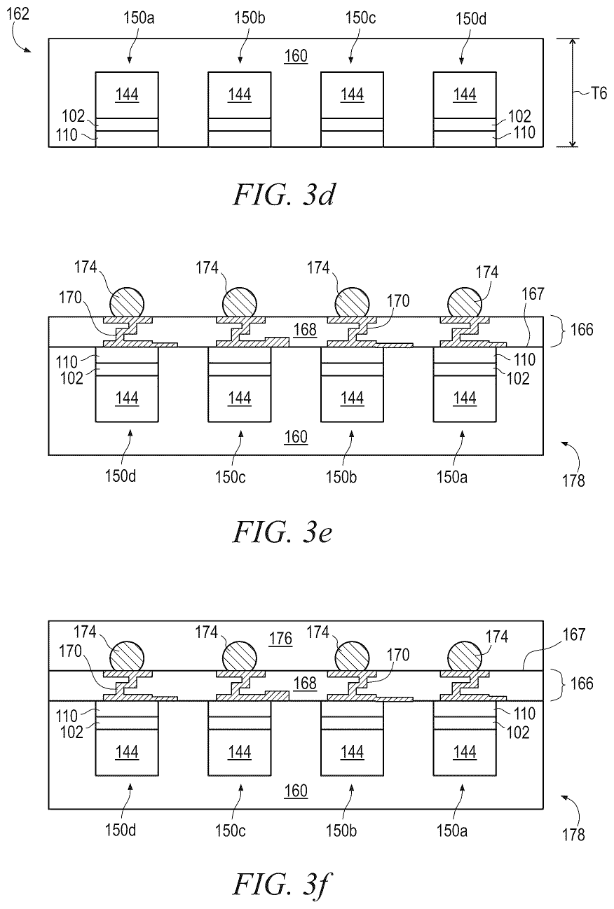

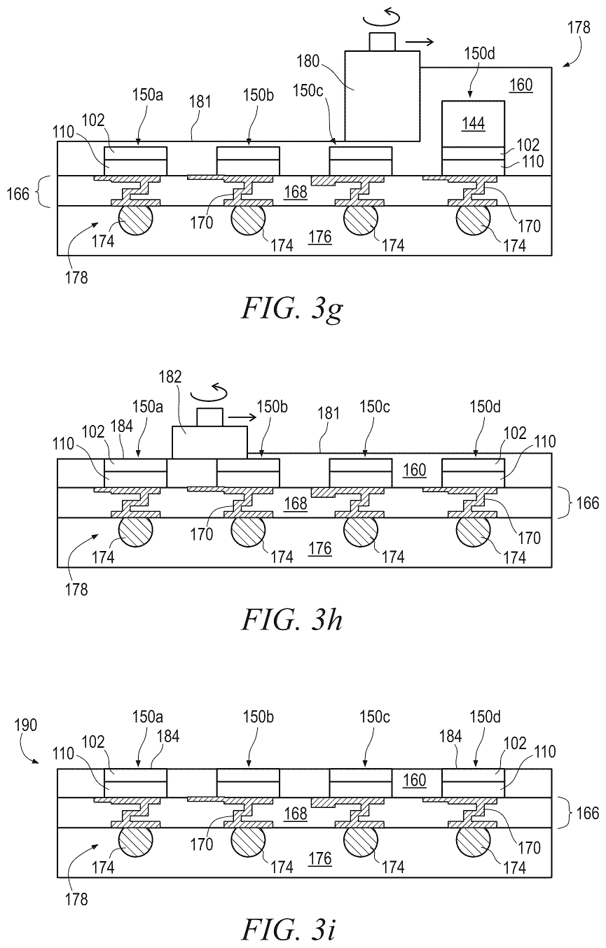

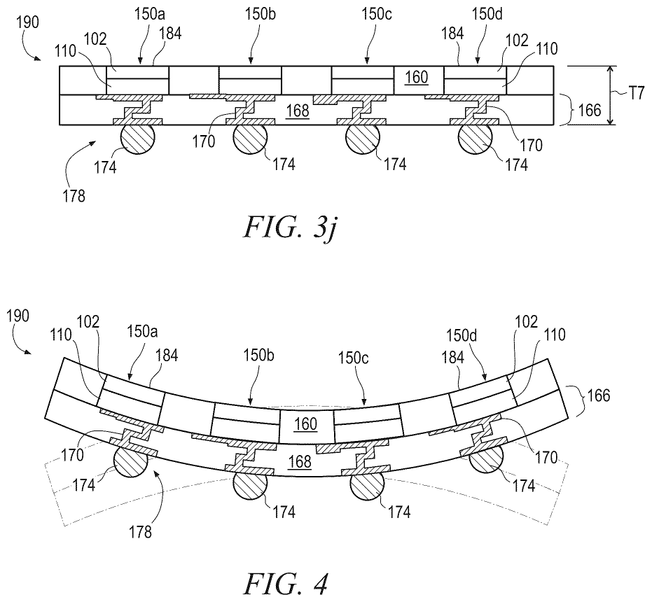

In FIG. 3a, semiconductor die 150a-150d are mounted to thermal release tape 154 using a pick and place operation. FIG. 3b shows semiconductor die 150a-150d mounted to thermal release tape 154. In FIG. 3c, assembly 156, including semiconductor die 150a-150d mounted to thermal release tape 154, is disposed within chase mold 158, similar to FIGS. 2k-2l. An encapsulant 160 is injected into the compartment between upper chase mold housing 158a and lower chase mold housing 158b and deposited over semiconductor die 150a-150d as disposed within chase mold 158. Encapsulant 160 can be polymer composite material, such as epoxy resin with filler, epoxy acrylate with filler, or polymer with proper filler. Encapsulant 160 is non-conductive, provides structural support, and environmentally protects the semiconductor device from external elements and contaminants.

In FIG. 3d, assembly 162, comprising semiconductor die 150a-150d with encapsulant 160, are removed from chase mold 158. In one embodiment, encapsulant 160 has a thickness T6 of 500 μm. In FIG. 3e, a build-up interconnect structure 166 is formed over surface 167 of encapsulant 160 and active layer 110 of semiconductor die 150a-150d. Build-up interconnect structure 166 includes one or more conductive layers 170 and one or more insulating layers 168. Conductive layers 170 can be one or more layers of Al, Cu, Sn, Ni, Au, Ag, or other suitable electrically conductive material. Conductive layers 170 can be formed using PVD, CVD, electrolytic plating, electroless plating process, or other suitable metal deposition process. Conductive layers 170 provide horizontal electrical interconnect across assembly 162 and vertical electrical interconnect. Portions of conductive layers 170 can be electrically common or electrically isolated depending on the design and function of semiconductor die 150a-150d and other electrical components. Insulating layers 168 contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layers 168 can be formed using PVD, CVD, printing, lamination, spin coating, spray coating, sintering or thermal oxidation. Insulating layers 168 provide isolation between conductive layers 170. There can be multiple conductive layers like 170 separated by insulating layers 168.

An electrically conductive bump material is deposited over conductive layer 170 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 170 using a suitable attachment or bonding process. In one embodiment, the bump material is reflowed by heating the material above its melting point to form balls or bumps 174. In one embodiment, bump 174 is formed over a UBM having a wetting layer, barrier layer, and adhesive layer. Bump 174 can also be compression bonded or thermocompression bonded to conductive layer 170. Bump 174 represents one type of interconnect structure that can be formed over conductive layer 170. The interconnect structure can also use bond wires, conductive paste, stud bump, micro bump, or other electrical interconnect. The combination of semiconductor die 150a-150d, encapsulant 160, build-up interconnect structure 166, and bumps 174 constitute assembly 178.

In FIG. 3f, backgrinding tape 176 is applied over build-up interconnect structure 166 and bumps 174. In FIG. 3g, assembly 178 is inverted and undergoes a first backgrinding operation using grinder 180 to remove a portion of encapsulant 144 and encapsulant 160 down to surface 181. About 10-20 mm of encapsulant 144 remains over semiconductor material 102 after the first grinding operation. In FIG. 3h, assembly 178 undergoes a second backgrinding operation using grinder 182 to remove the remainder of encapsulant 144 and expose semiconductor material 102 down to surface 184. FIG. 3i shows assembly 178 post grinding.

In FIG. 3j, backgrinding tape 176 is removed leaving semiconductor package 190. In one embodiment, semiconductor package 190 can be an embedded wafer level ball grid array (eWLB) fan-out wafer level package (FOWLP). Semiconductor die 150a-150d have a thickness T7 less than 100 μm, and preferably about 70 μm, with exposed die surfaces. Yet the process and structure described herein, including Z1 grinding and Z2 grinding in FIGS. 2a-2o and 3a-3j, reduces the risk of warpage and handling issues for subsequent manufacturing processes.

FIG. 4 illustrates flexibility of eWLB FOWLP 190 and reduced risk of warpage and handling issues for subsequent manufacturing processes.

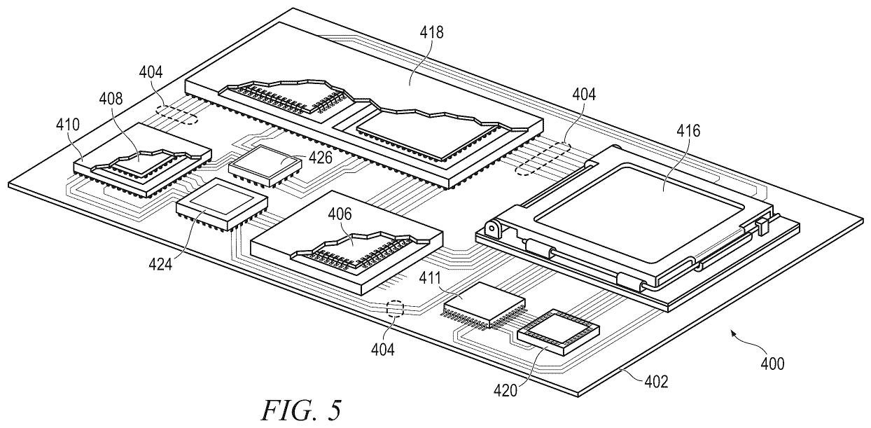

FIG. 5 illustrates electrical device 400 having a chip carrier substrate or PCB 402 with a plurality of semiconductor packages disposed on a surface of PCB 402, including semiconductor package 190. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 5, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor substrate;
forming a notch around a perimeter of the semiconductor substrate;
depositing a first encapsulant over the semiconductor substrate;
singulating the semiconductor substrate into a plurality of semiconductor die;
disposing the semiconductor die on a carrier as a reconstituted substrate; and
depositing a second encapsulant over the reconstituted substrate.

2. The method of claim 1, further including removing a portion of the semiconductor substrate.

3. The method of claim 1, further including removing a portion of the second encapsulant.

4. The method of claim 1, further including forming an interconnect structure over the semiconductor die and second encapsulant.

5. The method of claim 4, further including forming a plurality of bumps over the interconnect structure.

6. The method of claim 1, further including forming a curved surface around a perimeter of the semiconductor substrate.

7. A method of making a semiconductor device, comprising:
providing a semiconductor substrate;
singulating the semiconductor substrate into a plurality of semiconductor die;
disposing the semiconductor die on a carrier as a reconstituted substrate; and
depositing a first encapsulant over the reconstituted substrate.

8. The method of claim 7, further including:
forming a notch around a perimeter of the semiconductor substrate; and
depositing a second encapsulant over the semiconductor substrate.

9. The method of claim 7, further including removing a portion of the semiconductor substrate.

10. The method of claim 7, further including removing a portion of the first encapsulant.

11. The method of claim 7, further including forming an interconnect structure over the semiconductor die and first encapsulant.

12. The method of claim 11, further including forming a plurality of bumps over the interconnect structure.

13. The method of claim 7, further including forming a curved surface around a perimeter of the semiconductor substrate.

14. A semiconductor manufacturing system, comprising:
a semiconductor substrate including a plurality of semiconductor die and a notch formed around a perimeter of the semiconductor substrate;
a first encapsulant deposited over the semiconductor substrate;
the semiconductor die being disposed on a carrier as a reconstituted substrate; and
a second encapsulant deposited over the reconstituted substrate.

15. The semiconductor manufacturing system of claim 14, further including an interconnect structure formed over the semiconductor die and second encapsulant.

16. The semiconductor manufacturing system of claim 15, further including a plurality of bumps formed over the interconnect structure.

17. The semiconductor manufacturing system of claim 14, wherein the semiconductor substrate includes a curved surface around a perimeter of the semiconductor substrate.

18. The semiconductor manufacturing system of claim 14, wherein a thickness of the semiconductor die is less than 100 micrometers.

19. The semiconductor manufacturing system of claim 14, wherein the reconstituted substrate includes a flexible property.

20. A semiconductor manufacturing system, comprising:
a semiconductor substrate including a plurality of semiconductor die;
the semiconductor die being disposed on a carrier as a reconstituted substrate; and
a first encapsulant deposited over the reconstituted substrate.

21. The semiconductor manufacturing system of claim 20, further including:
a notch formed around a perimeter of the semiconductor substrate; and
a second encapsulant deposited over the semiconductor substrate.

22. The semiconductor manufacturing system of claim 20, further including an interconnect structure formed over the semiconductor die and first encapsulant.

23. The semiconductor manufacturing system of claim 22, further including a plurality of bumps formed over the interconnect structure.

24. The semiconductor manufacturing system of claim 20, wherein the semiconductor substrate includes a curved surface formed around a perimeter of the semiconductor substrate.

25. The semiconductor manufacturing system of claim 20, wherein a thickness of the semiconductor die is less than 100 micrometers.
